(19) United States
(12) Patent Application Publication
(10) Pub. No.: US 2011/0308773 A1
(43) Pub. Date: Dec. 22, 2011

(54) GRANULAR ABRASIVE CLEANING OF AN EMITTER WIRE

(75) Inventors: Guilian Gao, San Jose, CA (US); Nels Jewell-Larsen, San Jose, CA (US); Chung-Chuan Tseng, San Jose, CA (US)

(73) Assignee: TESSERA, INC., San Jose, CA (US)

(21) Appl. No.: 12/819,966

(22) Filed: Jun. 21, 2010

(51) Int. Cl. H05K 7/20; B24B 31/00

(52) U.S. Cl. 165/104.34; 165/95; 451/103; 451/36

(57) ABSTRACT

An apparatus for cleaning an emitter electrode in electrohydrodynamic fluid accelerator and precipitator devices via movement of a cleaning device including granular abrasives positioned to frictionally engage the emitter electrode. The cleaning device causes the granular abrasives to travel along a longitudinal extent of the emitter electrode to remove detrimental material accumulated on the electrode. The granular abrasives can be retained in housing, on opposed cleaning surfaces, and can be compressed by the housing or an applied force to abrade detrimental material from the electrode surface.

### BACKGROUND

1. Field of the Invention

This application relates generally to cleaning of electrodes in electrohydrodynamic or electrostatic devices such as electrohydrodynamic fluid accelerators and electrostatic precipitators.

Many electronic devices and mechanically operated devices require air flow to help cool certain operating systems by convection. Cooling helps prevent device overheating and improves long term reliability. It is known to provide cooling air flow with the use of fans or other similar moving mechanical devices; however, such devices generally have limited operating lifetimes, produce noise or vibration, consume power or suffer from other design problems.

The use of an ion flow air mover device, such as an electrohydrodynamic (EHD) device or electro-fluid dynamic (EFD) device, may result in improved cooling efficiency, reduced vibrations, power consumption, electronic device temperatures, and noise generation. This may reduce overall device lifetime costs, device size or volume, and may improve electronic device performance or user experience.

In many EHD or EFA devices and other similar devices, detrimental material such as silica dendrites, surface contaminants, particulates or other debris may accumulate or form on electrode surfaces and may decrease the performance, efficiency and lifetime of such devices. In particular, siloxane vapor breaks down in a plasma or corona environment and forms solid deposits of silica on the electrode, e.g., emitter or collector electrode. Other detrimental materials may also build up on various electrode surfaces. Buildup of such detrimental materials can decrease efficiency, performance and reliability, cause sparking or reduce spark-over voltage and contribute to device failure. Periodic removal of these deposits is needed to restore performance and reliability.

Accordingly, improvements are sought in cleaning and conditioning electrode surfaces.

2. Description of the Related Art

Devices built using the principle of the ionic movement of a fluid are variously referred to in the literature as ionic wind machines, electric wind machines, corona wind pumps, electro-fluid-dynamics (EFD) devices, electrohydrodynamic (EHD) thrusters and EHD gas pumps. Some aspects of the technology have also been exploited in devices referred to as electrostatic air cleaners or electrostatic precipitators.

In general, EHD technology uses ion flow principles to move fluids (e.g., air molecules). Basic principles of EHD fluid flow are reasonably well understood by persons of skill in the art. Accordingly, a brief illustration of ion flow using corona discharge principles in a simple two electrode system sets the stage for the more detailed description that follows.

With reference to the illustration in FIG. 1, EHD principles include applying a high intensity electric field between a first electrode 10 (often termed the “corona electrode,” the “corona discharge electrode,” the “emitter electrode” or just the “emitter”) and a second electrode 12. Fluid molecules, such as surrounding air molecules, near the emitter discharge region 11, become ionized and form a stream 14 of ions 16 that accelerate toward second electrode 12, colliding with neutral fluid molecules 22. During these collisions, momentum is imparted from the stream 14 of ions 16 to the neutral fluid molecules 22, inducing a corresponding movement of fluid molecules 22 in a desired fluid flow direction, denoted by arrow 13, toward second electrode 12. Second electrode 12 may be variously referred to as the “accelerating,” “attracting,” “target” or “collector” electrode. While stream 14 of ions 16 is attracted to, and generally neutralized by, second electrode 12, neutral fluid molecules 22 continue past second electrode 12 at a certain velocity. The movement of fluid produced by EHD principles has been variously referred to as “electric,” “corona” or “ionic” wind and has been defined as the movement of gas induced by the movement of ions from the vicinity of a high voltage discharge electrode 10.

### SUMMARY

It has been discovered that an electrohydrodynamic (EHD) emitter electrode may be cleaned of silica deposits using a cleaning device having granular abrasives held in frictional contact with the emitter electrode. The granular abrasives cause detrimental material, such as silica accumulated thereon during EHD device operation to be effectively broken up and wiped off to thereby restore electrode performance and reliability.

In some implementations, the emitter electrode is an elongated wire that, when energized, contributes to flow of ion current in one of an electrohydrodynamic fluid accelerator and an electrostatic precipitator.

In some implementations, the granular abrasives are loosely retained in a housing to permit movement of the granular abrasives within the housing. This movement presents fresh cleaning edges of the granular abrasives to the electrode over time.

In some cases, the granular abrasives are retained within a shrink tubing housing. In a particular case, the shrink tubing housing is periodically shrunk by heating of the electrode to reapply a compressive force to the granular abrasives in contact with the electrode.

In some implementations, the granular abrasives are retained by a cleaning device pad. For example, the granular abrasives can be retained in recesses in the face of a cleaning device pad. In some cases the cleaning device pad is formed of a wearable material such that movement of the cleaning device causes cleaning of the electrode by the granular abrasives and coating of the electrode by the wearable material.

In some cases, the granular abrasives include one or more of graphite, carbon, silica, alumina, granulated plastic, ceramic, copper, oxides of copper, silver, oxides of silver, manganese, oxides of manganese. Any number of other natural or synthetic minerals or sufficiently hard materials may be suitable for abrasive cleaning of detrimental materials accumulated on an electrode surface.

In some cases, the wearable material of the cleaning device pad includes one or more of carbon, silver, platinum, magnesium, manganese, palladium, nickel, or oxides or alloys of the same.

In some implementations, the emitter electrode is lightly clamped between two opposing cleaning device pads, one or both of the cleaning device pads bearing granular abrasives for cleaning the emitter electrode.

In some implementations, a single cleaning device pad may travel along different portions of the electrode to clean the entire electrode over several cleaning cycles.

In some implementations, the granular abrasives or the cleaning device pads bearing the granular abrasives may be at least partially retracted from contact with the electrode during electrode operation. For example, a compressive force may be applied to the granular abrasives during cleaning operations and the compressive force may be released during electrode operation. Similarly, cleaning device pads may be withdrawn from contact with the electrode after a cleaning cycle is complete. Withdrawal of the cleaning device from the electrode can prevent interference with the electrode during electrode operation. For example, withdrawal of the cleaning device may reduce sparking during electrode operation.

In some implementations, the cleaning device presents both granular abrasives and conditioning materials in contact with the electrode. In some cases, the granular abrasives are at least partially retained by the conditioning material. In some cases, the granular abrasives are released from the conditioning material as the conditioning material wears over time.

In some cases, a cleaning device pad includes discreet regions of granular abrasives and conditioning materials. For example, granular abrasives such as granulated plastic may be retained along a portion of a cleaning device pad formed of a conditioning material, such as carbon.

In some implementations, the cleaning device is further configured to elastically deform the electrode to break up materials accumulated on the electrode surface for removal by the granular abrasives. In some implementations, complementary cleaning device pads are contoured to induce a bend in the electrode sufficient to break up surface deposits without causing plastic deformation of the electrode.

In some implementations, the EHD device is part of a thermal management assembly for use in convective cooling of one or more devices within an enclosure. The thermal management assembly defines a flow path for conveyance of air between portions of the enclosure over heat transfer surfaces positioned along the flow path to dissipate heat generated by the one or more devices. The thermal management assembly includes an electrohydrodynamic (EHD) fluid accelerator including collector and emitter electrodes energizable to motivate fluid flow along the flow path, wherein at least one of the electrodes is susceptible to accumulation of detrimental material during operation thereof. A cleaning device includes granular abrasives in frictional engagement with the emitter electrode and moveable to remove detrimental material accumulated on the emitter electrode.

In some implementations, the cleaning device is moveable in response to detection of one of a low thermal duty cycle, power-on cycle and a power-off cycle of the one or more devices, sparking, voltage levels, current levels, acoustic levels, and detection of performance degradation.

In some implementations, the one or more devices includes one of a computing device, projector, copy machine, fax machine, printer, radio, audio or video recording device, audio or video playback device, communications device, charging device, power inverter, light source, medical device, home appliance, power tool, toy, game console, television, and video display device.

In some applications, a method of removing detrimental material from an electrode includes positioning a cleaning device in frictional engagement with the electrode and transiting one of the cleaning device and the electrode relative to the other of the cleaning device and the electrode to thereby remove detrimental material accumulated on the electrode. The cleaning device includes granular abrasives in frictional contact with the emitter electrode.

In some applications, the method further includes elastically deforming the electrode to break up detrimental material accumulated on the electrode.

In some applications, the method further includes depositing a conditioning material on the electrode in situ via transiting of the one of the cleaning device and the electrode. In some cases, a portion of the cleaning device is wearable to form a sacrificial conditioning coating selected, e.g., to mitigate electrode oxidation or to reduce ozone.

In some applications, the transiting is performed in response to detection of one of a low thermal duty cycle, power on cycle and a power off cycle of an electronic device, sparking, voltage levels, current levels, acoustic levels, and detection of performance degradation of the electrode.

### BRIEF DESCRIPTION OF THE DRAWINGS

The present invention may be better understood, and its numerous objects, features, and advantages made apparent to those skilled in the art by referencing the accompanying drawings.

FIG. 1 is a depiction of certain basic principles of electrohydrodynamic (EHD) fluid flow.

FIG. 2 depicts a cross-sectional side view of an electrode cleaning device including granular abrasives, in accordance with various implementations.

FIG. 3A depicts a side view of a cleaning device having opposed cleaning pads bearing granular abrasives, in accordance with various implementations.

FIGS. 3B-3D depict end views of the cleaning device of FIG. 3A having opposed cleaning pads bearing granular abrasives in contact with electrodes of various cross-sectional geometries, in accordance with various implementations.

FIG. 4 illustrates a side view of a cleaning device including a compression housing retaining granular abrasives for cleaning an elongated emitter electrode, in accordance with various implementations.

FIG. 5 is side view of a cleaning device bearing granular abrasives and partially enclosing an elongated emitter electrode, in accordance with various implementations.

FIG. 6 is a side view of a cleaning device including granular abrasives and contoured complementary cleaning pads for elastically deforming an electrode.

FIG. 7 depicts a translatable cleaning device slidably fitted on opposed collector electrodes and positioning cleaning pads in contact with the collector electrodes and granular abrasives in contact with an emitter electrode for tandem cleaning of the electrodes.

FIG. 8 depicts an electronic system employing an implementation of an EHD device subject to cleaning of accumulated material as described herein.

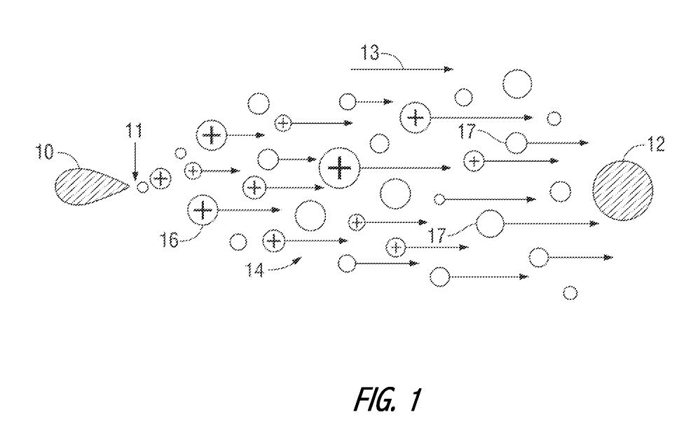

The use of like reference symbols in different drawings indicates similar or identical items.

### DESCRIPTION OF THE PREFERRED EMBODIMENT(S)

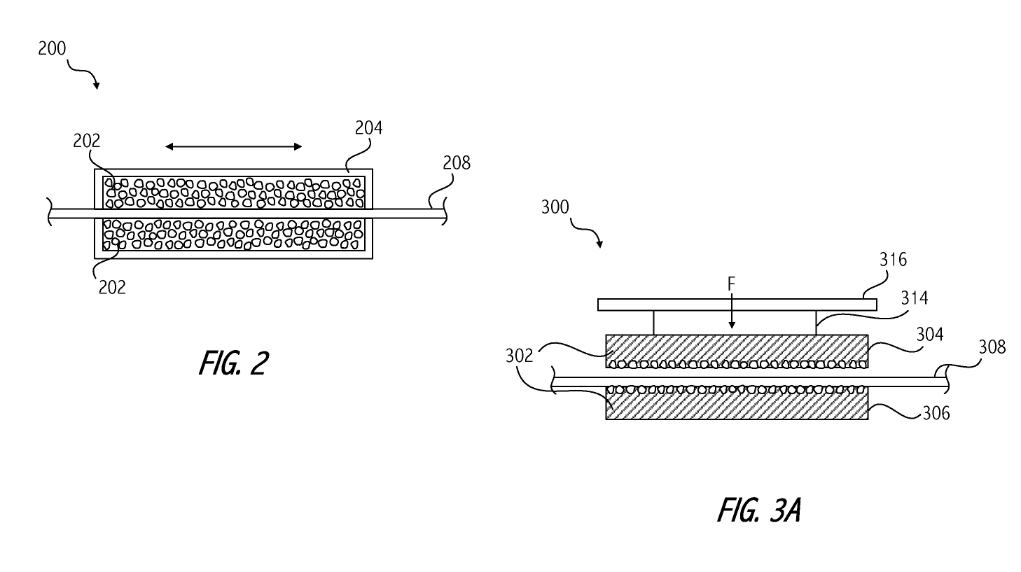

With reference to FIG. 2, a cleaning device 200 includes granular abrasives 202 in frictional contact with an emitter electrode 208 for frictional removal of detrimental material accumulated thereon.

In some implementations, cleaning device 200 is moveable along a longitudinal extent of emitter electrode 208 to thereby remove detrimental material such as silica dendrites, surface contaminants, particulate or other debris from the respective electrode surfaces. In some implementations, cleaning device 200 is fixed and electrode 208 is moveable relative to cleaning device 200.

In some implementations, granular abrasives 202 are generally compressed by a housing 204, but may be allowed to shift, tumble or otherwise be repositioned or reordered during relative movement of the emitter electrode 208 or cleaning device 200. Such a repositioning or reordering of granular abrasives 202 can provide fresh cleaning edges, surfaces or orientations of granular abrasives 202 in contact with emitter electrode 208, e.g., to maintain cleaning effectiveness over periodic cleaning cycles. Abrasive grain mobility can also prevent build-up of cast-off or dislodged detrimental material between the grains, which material could otherwise increase friction and decrease the cutting efficiency of the grains. Additionally, mobile granular abrasives 202 may wear without producing a groove as would generally occur with wearing of a monolithic frictional cleaning surface.

In some implementations, housing 204 may be formed of an elastic material to provide inward compression on granular abrasives 202 against emitter electrode 208.

In some implementations, granular abrasives 202 can be initially fixed in position or orientation by housing 204. For example, adhesion between grains, between grains and a backing, or between grains and matrix may serve to control how quickly grains are worn, exposed, or released. For example, granular abrasives 202 may be initially retained in a matrix or binder formed, for example, of clay, resin, glass or rubber.

Granular abrasives 202 may be of any size and shape and are preferably selected to provide for removal of surface accumulation on an electrode without undue abrasion of the electrode material itself. Individual grains need only be sufficiently large to cut through or otherwise break up accumulated materials on the electrode surface under a selected applied compression or force. In some cases, the granular abrasives 202 are relatively uniform beads. In some cases, granular abrasives 202 are coarse grains of material of varying shape and size.

Granular abrasives 202 can include a variety of materials in the composition of individual grains and in the combination of various grains. For example, in a particular implementation, grains of carbon and aluminum oxide are retained within a housing 204, e.g., an elastic shell.

Granular abrasives 202 generally include various grains or grit having rough edges or points to provide localized contact pressure. The granular abrasives 202 and the electrode are brought into contact while in relative motion to each other. Force applied through granular abrasives 202 causes fragments of accumulated material to break away from the electrode surface. Grains of granular abrasives 202 may be worn during cleaning and may work loose from a binder or be loosely retained adjacent other grains of the granular abrasives 202.

In some implementations, suitable granular abrasives include one or more of silica, alumina, aluminum oxide, granulated plastic, ceramic, carbon, graphite, copper, oxides of copper, silver, oxides of silver, manganese, oxides of manganese, calcite, corundum, novaculite, pumice, iron oxide, and glass powder.

In some applications, a wearable conditioning material can be delivered to the electrode during cleaning operations. Such conditioning material can serve as a lubricant to prevent loading of the abrasive matrix with swarf or can serve to mitigate abrasion of the electrode material itself. In some cases, the conditioning material may serve to provide enhanced electrode performance, e.g., ozone reduction. In some applications, abrasion and application of a conditioning material are performed simultaneously during cleaning operations.

The housing can be a unitary enclosure or can include multiple sections. One or more housing portions or sections can be withdrawn from contact with the electrode during electrode operation. Alternatively, an end portion of the electrode may be provided with insulation coating adjacent which the granular abrasive rests during operation of the electrode. In some cases, the cleaning device is stowed away from the active region of the electrode during electrode operation.

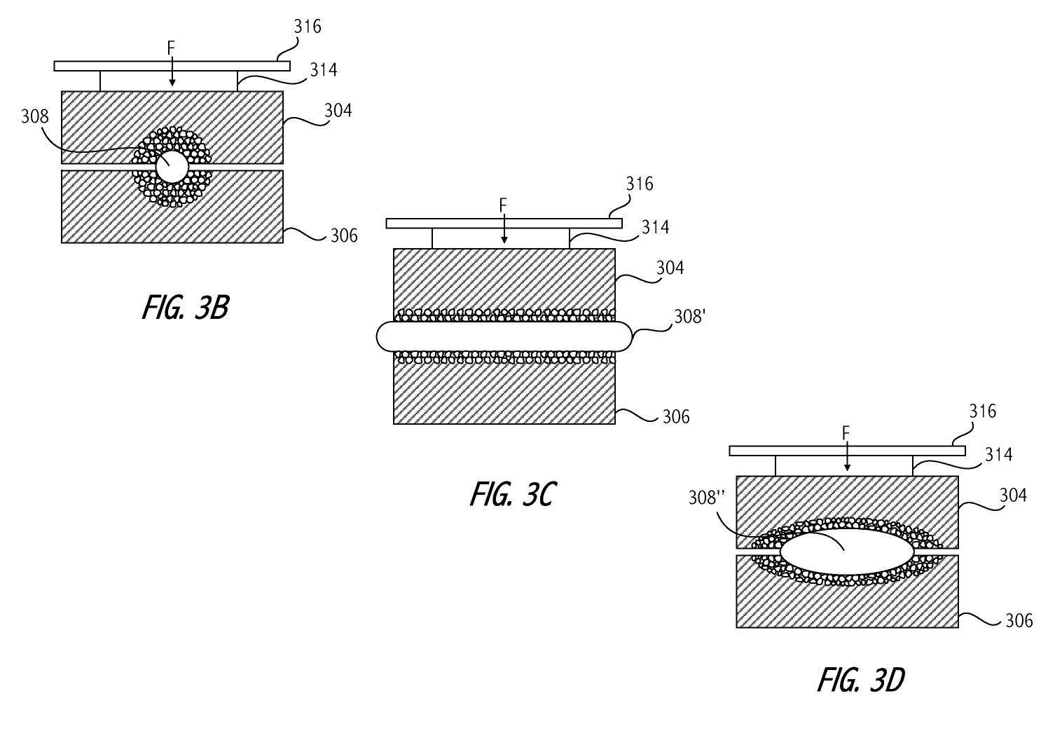

With reference to FIGS. 3A-3D, a cleaning device 300 includes cleaning pads 304 and 306 positioned to frictionally engage at least a portion of an elongated emitter electrode 308, 308′, 308″. Cleaning pads 304 and 306 present granular abrasives 302 to contact electrode 308 to remove dendrites or other detrimental material or to otherwise clean or condition electrode 308.

FIGS. 3B-3D depict end views of the cleaning device of FIG. 3A having opposed cleaning pads bearing granular abrasives in contact with electrodes of various cross-sectional geometries.

In some implementations, the respective opposed cleaning pads 304 and 306 are urged towards one another and the granular abrasives are compressed against the emitter electrode 308 by an applied force “F.” Applied force “F” can be provided by a compressed foam block 314, spring clamp, actuator or other mechanism disposed between at least one of the cleaning pads 304, 306 and a corresponding support structure 316. Cleaning pad 304 and foam block 314 are arranged to provide pressure between cleaning pad 304 and electrode 308 sufficient for granular abrasives 302 to frictionally clean electrode 308. In some cases, applied force “F” may be generated by an interference or compression fit between a cleaning device and an electrode or via a clamping device acting on the cleaning device. In some implementations, applied force “F” may be provided between a cleaning pad and an electrode or between opposed cleaning pads by magnetic repulsion, fringing fields, solenoids, electrical repulsion, or any other means of providing a desired force.

Applied force “F” may be applied only during cleaning operations, for example, such that a cleaning pad is not held in contact with the electrode during electrode operation. Thus, in some implementations, cleaning pads 304 and 306 may be brought into contact with the electrode 308 only during cleaning operations. In some cases, contact between cleaning pads 304 and 306 may be used to indicate pad wear or an end of life state.

Cleaning pads 304, 306 may retain granular abrasives 302 in a variety of ways. For example, in some cases, granular abrasives 302 may be disposed in respective cavities formed in cleaning pads 304, 306. In some cases, granular abrasives 302 may be initially retained by a binder and may then be dislodged from the binder by movement during cleaning operations. In some cases, granular abrasives 302 may be released from cleaning pads 304, 306 as cleaning pads 304, 306 wear during cleaning operations.

Emitter electrode 308 may be energizable to generate ions and may be positioned relative to a collector electrode(s) to motivate fluid flow along a fluid flow path. Thus, emitter electrode 308 and a collector electrode(s) may at least partially define an EHD fluid accelerator. Any number of additional electrodes may be positioned upstream or downstream of the EHD fluid accelerator along the fluid flow path. For example, in some implementations, a collector electrode can be disposed upstream of the EHD fluid accelerator along the fluid flow path and can operate as an electrostatic precipitator. Additional cleaning surfaces can be provided to frictionally engage and travel over surfaces of the collector electrode(s) or additional electrodes independent of or in tandem with travel of cleaning device 300 along the longitudinal extent of emitter electrode 308.

Alternatively, in some implementations, emitter electrode 308 may be moveable relative to cleaning device 300. For example, cleaning device 300 may be trained in a loop about drive pulleys or may be wound about take-up and supply spools, or may be otherwise transited past cleaning device 300.

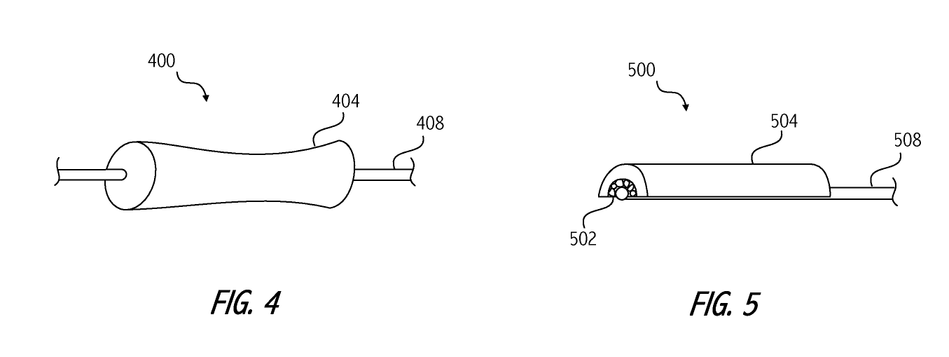

With reference to FIG. 4, in a particular implementation, housing 404 comprises an elastic membrane or shrink tube compressing granular abrasives against emitter electrode 408. In some cases, the material of housing 404 may be selected such that periodic heating of emitter electrode 408 causes housing 404 to contract in response to the heating to maintain inward compression of granular abrasives against emitter electrode 408. Such re-shrinking of housing 404 may be advantageous in cases where granular abrasives wear, shift, or otherwise diminish in collective volume over time.

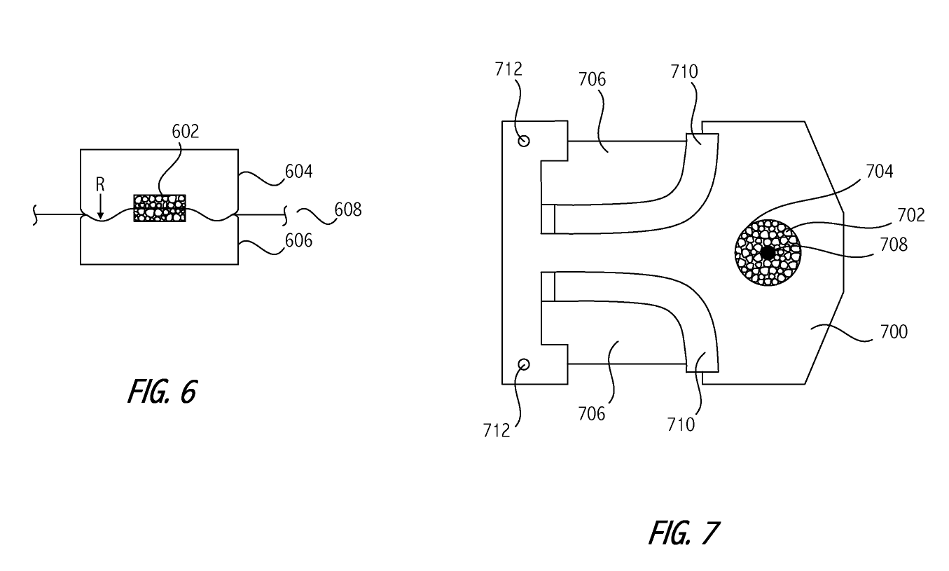

With reference to FIG. 5, a cleaning device 500 includes a housing 502 at least partially enclosing electrode 508 and retaining granular abrasives 502 in frictional contact with electrode 508. In some implementations, multiple cleaning passes may be used to provide full cleaning coverage by granular abrasives 502 in contact with electrode 508. In some cases, cleaning device 500 may travel a spiraling path along electrode 508 to provide full cleaning coverage of electrode 508.

With reference to FIG. 6, cleaning pads 604 and 606 retain granular abrasive 602 in one or more recesses formed therein. Cleaning pads 604 and 606 further define complementary surfaces contoured to induce a controlled bend in the elongated emitter electrode 608. The radius of the bend “R” is selected such that the ratio of the emitter electrode radius to the bend radius does not exceed the yield strain of the emitter wire material so as to avoid plastic, i.e. permanent, deformation. Such elastic deformation and controlled bending stresses help break up brittle silica deposits on the emitter electrode.

With continued reference to FIG. 6, cleaning pads 604 and 606 can include conditioning materials for surface conditioning of electrode 608. In some cases, cleaning pads 604 and 606 are formed of a conditioning material. Granular abrasives 602 may be replenished as needed or may be replaceable separately or in conjunction with cleaning pads 604, 606. Cleaning pads 604 and 606 can include similar or different conditioning materials. For example, one conditioning material composition can provide an electrode shielding composition to protect against oxidation, and another conditioning material composition can include an ozone reducer. Both electrode cleaning and conditioning can be performed by movement of cleaning pads 604, 606 along electrode 608.

In some implementations, the cleaning pads can include multiple cleaning or conditioning regions or surfaces. The cleaning pads can each include at least a first contoured region for breaking-up dendrites on the electrode through bending of the electrode, and at least a second region bearing granular abrasives 602 for abrading dendrites and other surface accumulations or detrimental materials on the surface of electrode 608.

In some implementations, cleaning blocks 604 and 606 are further configured to deposit a conditioning material coating on the electrode, e.g., through wearing of the cleaning pad. Thus, in some cases, bending, abrading and conditioning can be simultaneously performed by movement of the cleaning device. Cleaning device pads 604 and 606 may include any combination of surface profiles, including flat, curved, grooved, undulating, and the like to provide a desired degree of frictional contact and/or electrode deformation during cleaning. Various electrodes may be formed as a wire, bar, array, block, strip, or other form and the cleaning device 600 can be constructed to clean any desired portion of surfaces of the electrodes with granular abrasives 602.

With continued reference to FIG. 6, cleaning pads 604 and 606 may be periodically replaced as needed. In some implementations, cleaning pads 604 and 606 are independently replaceable or are replaceable as a set. In some cases, operation of the cleaning device 600 may result in the removal of some of the cleaning pad material resulting in a groove forming or deepening in the cleaning pad(s) while granular abrasives 602 are less susceptible to groove formation.

While cleaning pads 604 and 606 are depicted as mating opposed counterparts on opposite surfaces of electrode 608, it will be understood that the invention is not limited to two-part cleaning pads for use with wire electrodes as shown in FIG. 6, but may include single cleaning shuttles, beads or other cleaning devices such as brushes, or multiple cleaning heads and surfaces for use with electrodes of other shapes. Cleaning device 600 may be used to remove detrimental material from respective electrode surfaces with single or multiple longitudinal passes or other movement, including lateral movement relative to a longitudinal extent of an electrode.

In a particular implementation, an elongated emitter electrode wire 608 is positioned in spaced relation, e.g., 1-5 mm, to a collector electrode and energizable to establish a corona discharge therebetween. The emitter electrode wire 608 is placed in tension, e.g., 10-30 g, and is cleaned using carbon granular abrasives 602 on cleaning pads 604 and 606, with a 40-80 g preload between the cleaning pads 604 and 606 and emitter electrode 608. The granular abrasive bearing cleaning pads 604, 606 are transited along the emitter electrode 608 at about 13 mm/s in both an initial pass and a return pass. The granular abrasives present on the cleaning pads 604, 606 are sufficiently hard to effectively remove detrimental material from electrode 608 and sufficiently soft to wear and deposit a carbon coating on electrode 608. Carbon is but one example of a granular abrasive that may be used. Other materials may be provided by cleaning pads 604, 606, e.g., to provide ozone reducing coatings, sacrificial coatings, electrode surface refinishing, electrode lubrication, or other useful conditioning of electrodes.

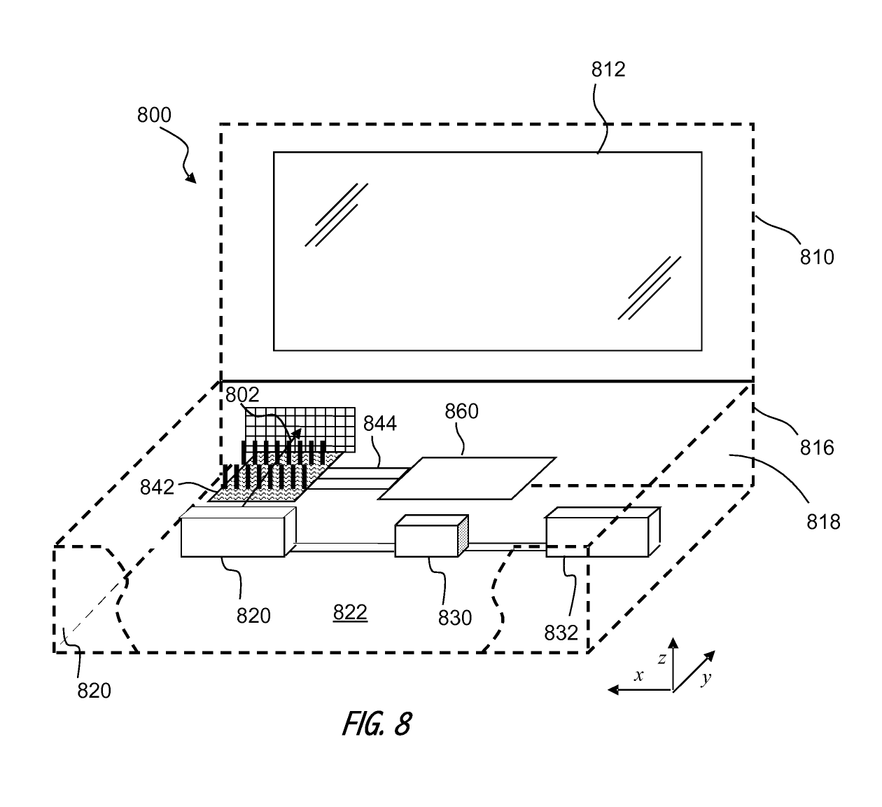

With reference to FIG. 7, cleaning device 700 includes granular abrasives 702 retained by housing 704 in frictional engagement with emitter electrode 708. Cleaning pads 710 engage collector electrodes 706. A drive cable 712 or other suitable drive structure is positioned behind the collector electrodes 706 away from emitter electrode 708. Such positioning of drive belt or drive cable 712 away from electrode 708 can reduce charging and sparking to drive cable 712 from electric fields around electrode 708 and can also help avoid interference with electric fields around electrode 708.

In some implementations, collector electrodes 706 serve as a guide for movement and alignment of cleaning device 700. In some cases, cleaning device 700 can be slidingly retained on electrode 706. For example, cleaning device 700 can extend between electrodes 706 with cleaning surfaces 710 retained adjacent respective surfaces of electrodes 706 by a sliding fit between complementary electrode, pad and cleaning device contours.

With continued reference to FIG., 7, granular abrasives 702 may travel along a longitudinal extent of emitter electrode 708 while respective cleaning pads 710 travel in tandem over a major dimension of a surface of collector electrodes 706 or other electrode(s). For example, an EHD or EFA device can also include grounding electrodes, repelling electrodes, backflow electrodes or other electrodes. Cleaning device 700 may be fitted with additional cleaning surfaces to be transited past any number of electrodes, filters, or other system features prone to detrimental material accumulation and in need of mechanical cleaning or other surface conditioning.

Cleaning device 700 can be driven or translated via a drive cable 712 trained about a drive pulley and idler pulley. Other types of drive mechanisms may be used to move cleaning device 700 to thereby clean and/or condition an electrode. Cleaning device 700 may be movable in single passes such that cleaning device 700 moves between alternate ends of electrodes 708 and 706 in each cycle. Alternatively, cleaning device 700 may reciprocate or move bidirectionally in a single cycle or it in may perform any combination of movements at selected speeds in a given cycle. The electrode may be energized and performance measured to determine a need for additional cleaning.

In some implementations, a secondary cleaning device, e.g., a brush, may be positioned to contact cleaning device leading edges or surfaces adjacent housing 704 or cleaning pads 710 where detrimental material dislodged from electrodes 706 or 708 may accumulate on cleaning device 700. Thus, swarf or other secondary detrimental material accumulation may be removed from cleaning device 700 including cleaning pads 702 and housing 704 by a brush or other suitable secondary cleaning device. Detrimental material dislodged by the brush can be accumulated in a receptacle area positioned adjacent a stowed position where the cleaning device 700 is stored between cleaning cycles. Accumulated particulate can be periodically discarded or may be otherwise exhausted from the system.

FIG. 8 is a schematic block diagram illustrating one implementation of an environment in which a cleaning device may operate. An electronic device 800, such as a computer, includes an EFA or EHD air cooling system 820. Electronic device 800 comprises a housing 816, or case, having a cover 810 that includes a display device 812. A portion of the front surface 821 of housing 816 has been cut away to reveal interior 822. Housing 816 of electronic device 800 may also comprise a top surface (not shown) that supports one or more input devices that may include, for example, a keyboard, touchpad and tracking device. Electronic device 800 further comprises electronic circuit 860 which generates heat in operation. A thermal management solution comprises a heat pipe 844 that draws heat from electronic circuit 860 to heat sink device 842.

Device 820 is powered by high voltage power supply 830 and is positioned proximate to heat sink 842. Electronic device 800 may also comprise many other circuits, depending on its intended use; to simplify illustration of this second implementation. Other components that may occupy interior area 822 of housing 820 have been omitted from FIG. 8.

With continued reference to FIG. 8, in operation, high voltage power supply 830 is operated to create a voltage difference between emitter electrodes and collector electrodes disposed in device 820, generating an ion flow or stream that moves ambient air toward the collector electrodes. The moving air leaves device 820 in the direction of arrow 802, traveling through the protrusions of heat sink 842 and through an exhaust grill or opening (not shown) in the rear surface 818 of housing 816, thereby dissipating heat accumulating in the air above and around heat sink 842. Note that the position of illustrated components, e.g., of power supply 830 relative to device 820 and electronic circuit 860, may vary from that shown in FIG. 8.

A controller 832 is connected to device 820 and may use sensor inputs to determine the state of the air cooling system, e.g., to determine a need for cleaning electrodes. Alternatively, the cleaning may be initiated by controller 832 on a timed or scheduled basis, on a system efficiency measurement basis or by other suitable methods of determining when to clean electrodes. For example, cleaning may be initiated following detection of a low thermal duty cycle, power on cycle and a power off cycle of electronic device 800. Similarly, electrode performance may be determined by monitoring voltage levels, current levels, acoustic levels, arcing, sparking, or other performance degradation or performance characteristics useful to initiate cleaning operations.

In some implementations, cleaning or other conditioning is performed when the electrode is not in use. Alternatively, cleaning operations may be performed at timed intervals. In some cases, conditioning or cleaning may be initiated by controller 832 based upon one or more of an imposed voltage level, a measured electrical potential, determination of the presence of a level of contamination by optical means, by detection of an event or performance parameter, or other methods indicating a benefit from mechanically cleaning the electrode.

Performance of an emitter electrode can deteriorate due to dendrite growth in a relatively short period of operation, e.g., 30-120 minutes. Accordingly, regular cleaning may be advantageously initiated as a function of detection of dendrite growth, according to a periodic schedule, or in response to various events, e.g., power cycles, electrode arcing or performance characteristics.

Some implementations of thermal management systems described herein employ EFA or EHD devices to motivate flow of a fluid, typically air, based on acceleration of ions generated as a result of corona discharge. Other implementations may employ other ion generation techniques and will nonetheless be understood in the descriptive context provided herein. Using heat transfer surfaces which may or may not be monolithic or integrated with collector electrodes, heat dissipated by electronics (e.g., microprocessors, graphics units, etc.) and/or other components can be transferred to the fluid flow and exhausted. Typically, when a thermal management system is integrated into an operational environment, heat transfer paths, e.g., heat pipes, are provided to transfer heat from where it is dissipated or generated to a location(s) within the enclosure where air flow motivated by an EFA or EHD device(s) flows over heat transfer surfaces.

In some implementations, an EFA or EHD air cooling system or other similar ion action device employing an electrode cleaning system may be integrated in an operational system such as a laptop or desktop computer, a projector or video display device, etc., while other implementations may take the form of subassemblies. Various features may be used with different devices including EFA or EHD devices such as air movers, film separators, film treatment devices, air particulate cleaners, photocopy machines and cooling systems for electronic devices such as computers, laptops and handheld devices. One or more devices includes one of a computing device, projector, copy machine, fax machine, printer, radio, audio or video recording device, audio or video playback device, communications device, charging device, power inverter, light source, medical device, home appliance, power tool, toy, game console, television, and video display device.

While the foregoing represents a description of various implementations of the invention, it is to be understood that the claims below recite the features of the present invention, and that other implementations, not specifically described hereinabove, fall within the scope of the present invention.

What is claimed is:

1. An apparatus comprising:
an electrode susceptible to accumulation of detrimental material during operation thereof; and
a cleaning device including granular abrasives held in frictional engagement with the electrode.

2. The apparatus of claim 1, wherein the cleaning device is adapted to travel over at least a substantial portion of a longitudinal extent of the electrode.

3. The apparatus of claim 1, wherein a position of the cleaning device is generally fixed and the electrode is configured to transit the generally fixed cleaning device.

4. The apparatus of claim 1, wherein the electrode, when energized, contributes to flow of ion current in one of an electrohydrodynamic fluid accelerator and an electrostatic precipitator.

5. The apparatus of claim 1, wherein the granular abrasives comprise at least one of silica, alumina, granulated plastic, ceramic, carbon, graphite, copper, oxides of copper, silver, oxides of silver, manganese, and oxides of manganese.

6. The apparatus of claim 1, wherein the granular abrasives are retained in one or more recesses in a cleaning pad.

7. The apparatus of claim 1, wherein the granular abrasives are softer than the electrode, such that the granular abrasives are wearable during relative movement between the cleaning device and the electrode.

8. The apparatus of claim 7, comprising an electrode conditioning material depositable in situ on the electrode via the cleaning device.

9. The apparatus of claim 1, wherein the electrode is energizable to motivate fluid flow along a flow path, the apparatus further comprising heat transfer surfaces along the flow path to dissipate heat from an electronic device.

10. The apparatus of claim 9, wherein at least one of the electrode and the cleaning device is moveable in response to detection of one of a low thermal duty cycle, power on cycle and a power off cycle of the electronic device, sparking, voltage levels, current levels, acoustic levels, and detection of performance degradation of the electrode.

11. The apparatus of claim 1, wherein the cleaning device includes opposed complementary contoured surfaces to elastically deform the electrode during movement of one of the cleaning device and the electrode.

12. The apparatus of claim 11, wherein the contoured surfaces are selected such that a ratio of the electrode radius to a minimum electrode deformation radius does not exceed the yield strain of the electrode.

13. An apparatus comprising:
an enclosure;
a thermal management assembly for use in convection cooling of one or more devices within the enclosure, the thermal management assembly defining a flow path for conveyance of air between portions of the enclosure over heat transfer surfaces positioned along the flow path to dissipate heat generated by the one or more devices, the thermal management assembly including an electrohydrodynamic (EHD) fluid accelerator including collector and emitter electrodes energizable to motivate fluid flow along the flow path, wherein at least one of the electrodes is susceptible to accumulation of detrimental material during operation thereof; and
a cleaning device including granular abrasives held in frictional engagement with the at least one electrode and moveable to travel along a longitudinal extent of the at least one electrode.

14. The apparatus of claim 13, wherein the cleaning device is moveable in response to detection of one of a low thermal duty cycle, power on cycle and a power off cycle of the one or more devices, sparking, voltage levels, current levels, acoustic levels, and detection of performance degradation of the electrode.

15. The apparatus of claim 13, wherein the one or more devices includes one of a computing device, computing tablet, projector, copy machine, fax machine, printer, radio, audio or video recording device, audio or video playback device, communications device, charging device, power inverter, light source, heat source, medical device, home appliance, power tool, toy, game console, television, and video display device.

16. A method of removing detrimental material from an electrode, the method comprising:
positioning a cleaning device including granular abrasives compressed in frictional engagement with the electrode; and
transiting one of the cleaning device and the electrode relative to the other of the cleaning device and the electrode to thereby remove detrimental material accumulated on the electrode.

17. The method of claim 16, further comprising depositing a conditioning material on the electrode in situ via transiting of the one of the cleaning device and the electrode.

18. The method of claim 16, wherein a portion of the cleaning device is wearable to deposit a conditioning material on the electrode.

19. The method of claim 18, wherein the conditioning material includes an ozone reducing material.

20. The method of claim 18, wherein the conditioning material forms a sacrificial coating selected to mitigate electrode oxidation.

21. The method of claim 16, wherein the electrode is one of an emitter electrode and a collector electrode.

22. The method of claim 16, wherein the transiting is performed in response to detection of one of a low thermal duty cycle, power on cycle and a power off cycle of an electronic device, sparking, voltage levels, current levels, acoustic levels, and detection of performance degradation of the electrode.
